(19) United States
(12) Patent Application Publication
(10) Pub. No.: US 2025/0309072 A1
(43) Pub. Date: Oct. 2, 2025

(54) SEMICONDUCTOR MODULE

(71) Applicant: FUJI ELECTRIC CO., LTD., Kawasaki-shi (JP)

(72) Inventors: Norihiro DAICHO, Kawasaki-shi (JP); Yoshihiro KODAIRA, Kawasaki-shi (JP)

(73) Assignee: FUJI ELECTRIC CO., LTD., Kawasaki-shi (JP)

(21) Appl. No.: 19/065,157

(22) Filed: Feb. 27, 2025

(30) Foreign Application Priority Data
Apr. 1, 2024 (JP) 2024-058590

(51) Int. Cl. H01L 23/495; H01L 23/055

(52) U.S. Cl. CPC H01L 23/49568; H01L 23/055; H01L 23/49531; H01L 23/49548

(57) ABSTRACT

A semiconductor module includes a circuit component including a wiring board on which a semiconductor element is mounted, a case having at a case front surface thereof a recess in which a nut is to be accommodated, and including a frame body surrounding a case opening in which the wiring board is disposed and a lid closing the case opening, and a lead including an external terminal extending in an extending direction along the case front surface, a bonded member bonded to the wiring board, and an intermediate member connecting the bonded member to the external terminal. The case has an abutting member that contacts the lead to prevent the lead from rotating about a boundary between the bonded member and the intermediate member, thereby preventing an increase in an angle between the extending direction of the external terminal portion and the case front surface.

### CROSS-REFERENCE TO RELATED APPLICATION

This application is based upon and claims the benefit of priority to Japanese Patent Application No. 2024-058590, filed on Apr. 1, 2024, the entire contents of which are incorporated herein by reference.

### BACKGROUND OF THE INVENTION

### 1. Technical Field

The present invention relates to a semiconductor module.

### 2. Description of the Related Art

Some semiconductor modules used in an inverter device include a lead having one end bonded to a conductor of a circuit component disposed in a case and the other end extending outwards through a gap of the case. As this type of semiconductor module, there is a semiconductor module capable of performing alignment between an external terminal portion extending to the outside of a case in a lead and the case with high accuracy (for example, WO 2017/122473 A and JP 2009-21286 A).

### SUMMARY OF THE INVENTION

However, in the above-described semiconductor module, a variation in parallelism between the external terminal portion of the lead and the surface (front surface) of the case easily occurs for each semiconductor module. An object of the present invention is to reduce a variation in parallelism between an external terminal portion of a lead and a surface (front surface) of a case for each semiconductor module.

A semiconductor module according to one aspect includes: a circuit component including a wiring board and a semiconductor element mounted on the wiring board; a lead bonded to a conductor pattern of the circuit component; and a case having a recessed portion formed in a front surface thereof, the recessed portion accommodating a nut. The case includes a frame body portion surrounding the wiring board and a lid portion closing an opening of the frame body portion. The lead includes an external terminal portion extending along the wiring board, a portion-to-be-bonded bonded to the conductor pattern, and an intermediate portion connecting the portion-to-be-bonded to the external terminal portion. The case is provided with an abutting portion abutting on the lead so as to prevent an increase in an angle of the external terminal portion of the lead in an extending direction relative to the wiring board, in which the increase in an angle is caused by rotation of the intermediate portion and the external terminal portion of the lead having a boundary between the portion-to-be-bonded and the intermediate portion as a fulcrum.

According to the above aspect, it is possible to reduce a variation in parallelism between an external terminal portion of a lead and a surface (front surface) of a case for each semiconductor module.

### BRIEF DESCRIPTION OF THE DRAWINGS

FIG. 1 is a plan view of a semiconductor module according to a first embodiment;

FIG. 2 is a cross-sectional view taken along line A-A′ in FIG. 1;

FIG. 3 is a perspective view illustrating an example of a shape of a lead;

FIG. 4 is a partially enlarged plan view in which the inside of a region B in FIG. 1 is enlarged;

FIG. 5 is a cross-sectional view taken along line C-C′ in FIG. 4;

FIG. 6 is an equivalent circuit diagram of an inverter circuit formed in the semiconductor module of FIG. 1;

FIG. 7 is a flowchart illustrating a manufacturing step of the semiconductor module according to the first embodiment;

FIG. 8 is a diagram illustrating floating of a main terminal;

FIG. 9 is a plan view of a semiconductor module according to a second embodiment;

FIG. 10 is a partially enlarged plan view in which the inside of a region D in FIG. 9 is enlarged;

FIG. 11 is a cross-sectional view taken along line E-E′ in FIG. 10;

FIG. 12 is a flowchart illustrating a manufacturing step of the semiconductor module according to the second embodiment; and

FIG. 13 is a diagram illustrating the effects of a configuration of the semiconductor module according to the second embodiment.

### DETAILED DESCRIPTION

Hereinafter, embodiments of the present invention will be described in detail with reference to the drawings. A “semiconductor module” in the following description is obtained by sealing semiconductor elements, which are referred to as semiconductor chips, dies, or the like, with an insulating material. The semiconductor module may be referred to as a “semiconductor device” or the like.

An X-axis, a Y-axis, and a Z-axis in the drawings are illustrated for the purpose of defining a plane and a direction in the illustrated semiconductor module and the like. The X-axis, the Y-axis, and the Z-axis are perpendicular to each other and form a right-handed system. In the following description, a direction parallel to the X-axis, a direction parallel to the Y-axis, and a direction parallel to the Z-axis are referred to as an X direction, a Y direction, and a Z direction, respectively. Further, in a case where each of the X direction, the Y direction, and the Z direction is associated with a direction of an arrow (positive or negative) of a corresponding one of the X-axis, the Y-axis, and the Z-axis illustrated, a “positive side” or a “negative side” is added.

In the present specification, the Z direction may be referred to as a vertical direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed on the member A”, the member B is disposed on the positive side in the Z direction as viewed from the member A. Further, when the “upper surface of the member A” is described, the surface may be a surface positioned at the end of the member A on the positive side in the Z direction and oriented toward the positive side in the Z direction. These directions and surfaces associated with the directions are words used for convenience of description, and a correspondence relationship with the directions of the X-axis, the Y-axis, and the Z-axis may change depending on the mounting orientation of the semiconductor module and the like. For example, in the present specification, a surface of a semiconductor element facing a wiring board is referred to as a lower surface, and a surface opposite to the lower surface is referred to as an upper surface, but the terms are not limited thereto, and the surface facing the wiring board may be referred to as the upper surface, and the surface opposite thereto may be referred to as the lower surface.

An aspect ratio and a magnitude relationship between respective members in each drawing are merely schematically represented, and do not necessarily coincide with a relationship in a semiconductor module actually manufactured. For convenience of description, it is also assumed that a magnitude relationship between respective members is exaggeratedly expressed, or an expression is different from an outer shape of a member used in an actual semiconductor module. Additionally, the underlined reference sign in the drawings indicates a reference sign for a whole component that encompasses a plurality of portions distinguished by a plurality of reference signs.

The descriptions of “not illustrated” and the like in the present specification are intended not to clearly indicate, by use of a specific reference sign and a leader line, which portion of the drawings is a component to which the descriptions are given. For example, a “first main electrode (not illustrated)” is intended to mean both that a portion representing the first main electrode (for example, a shape and a line) is not illustrated in the drawings, and that there is neither a reference sign nor a leader line clearly indicating a portion corresponding to the first main electrode in the drawings.

A semiconductor module to be illustrated in the following description may be applied to, for example, a power conversion apparatus such as an inverter apparatus of industrial or electrical equipment (for example, an in-vehicle motor). Thus, in the following description, detailed description of the same or similar configuration, function, operation, manufacturing method, and the like as or to those of a known semiconductor module will be omitted.

### First Embodiment

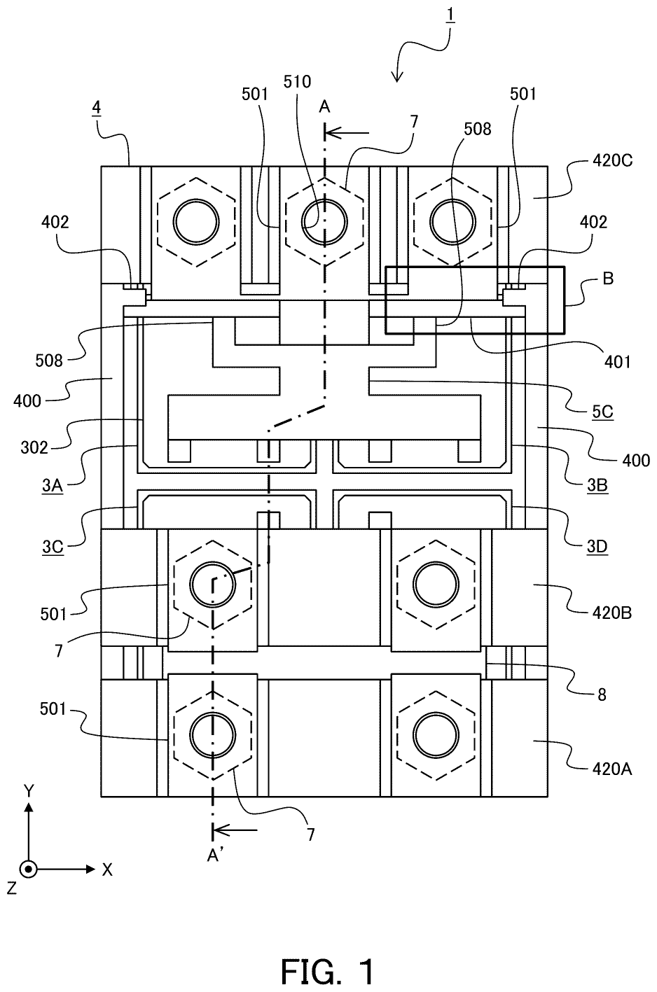

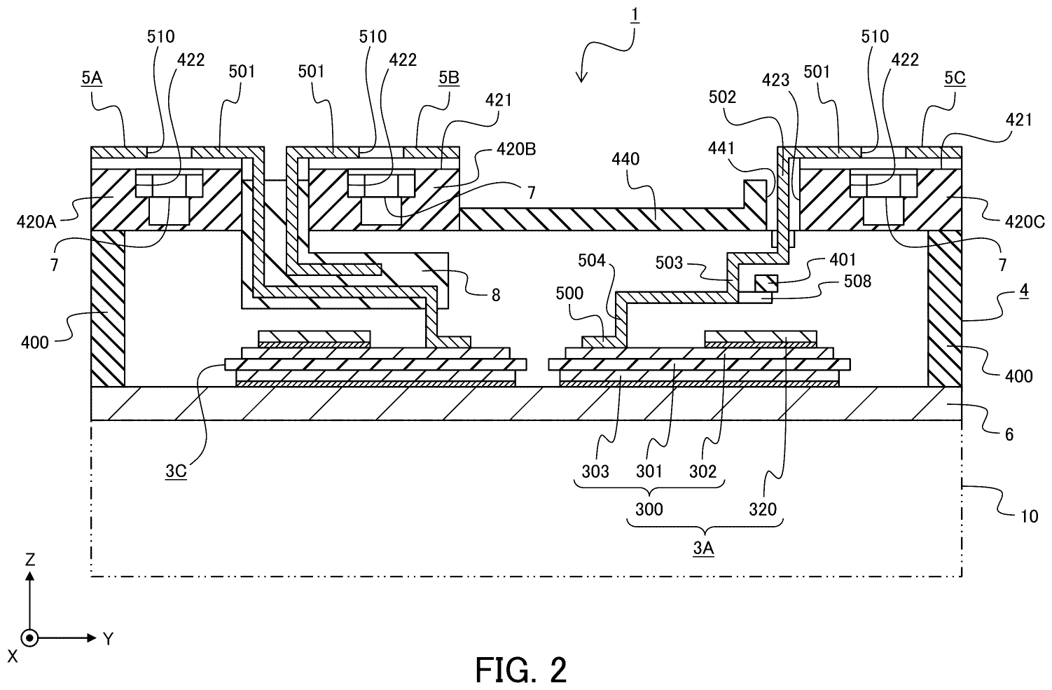

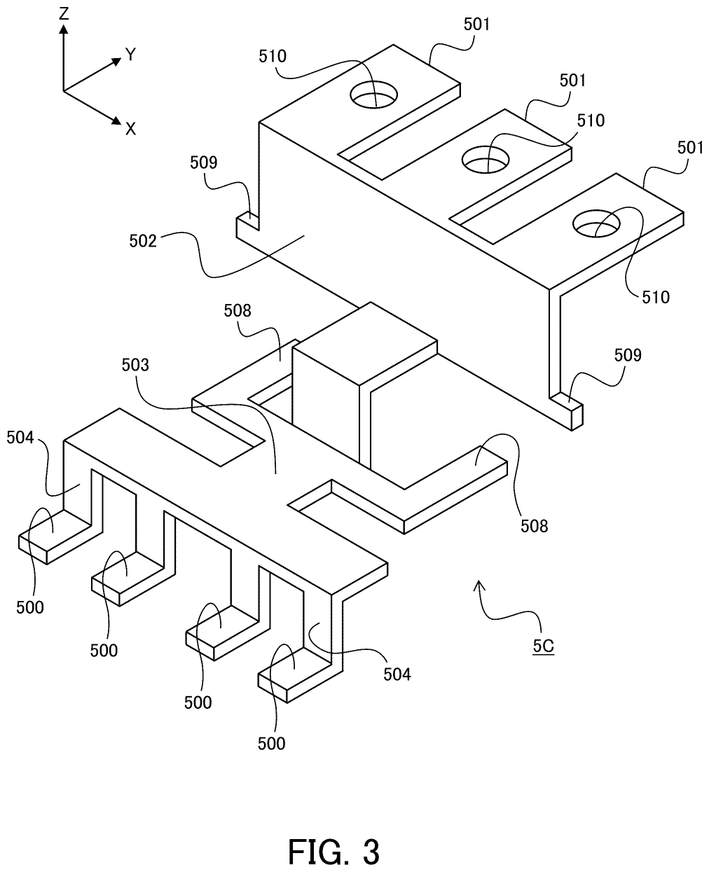

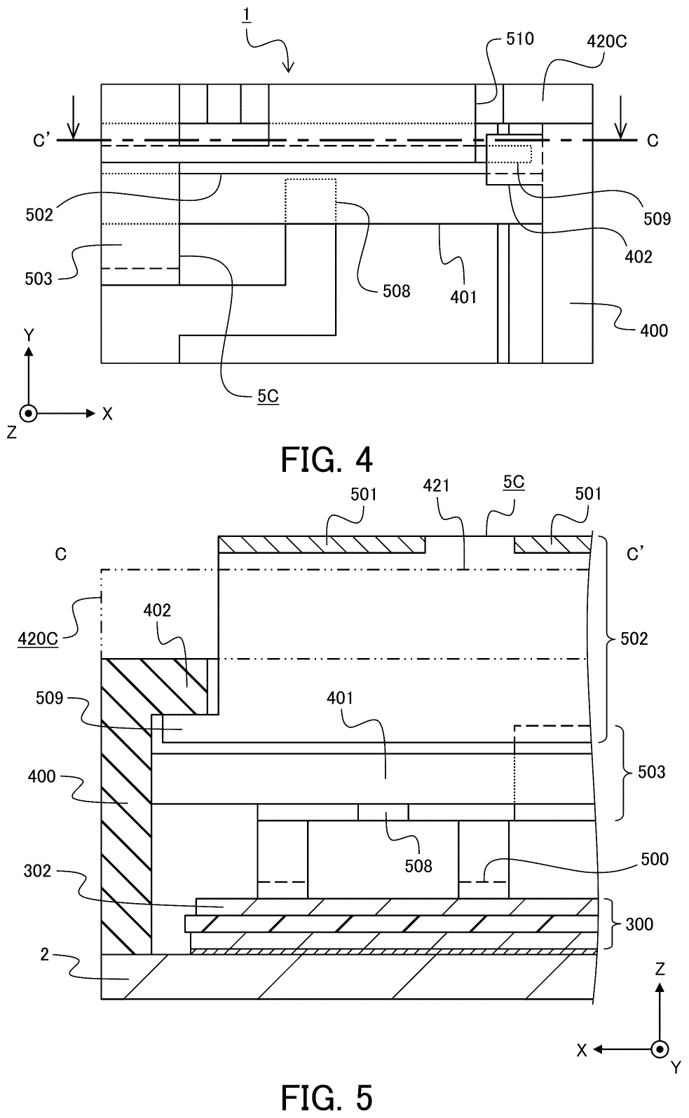

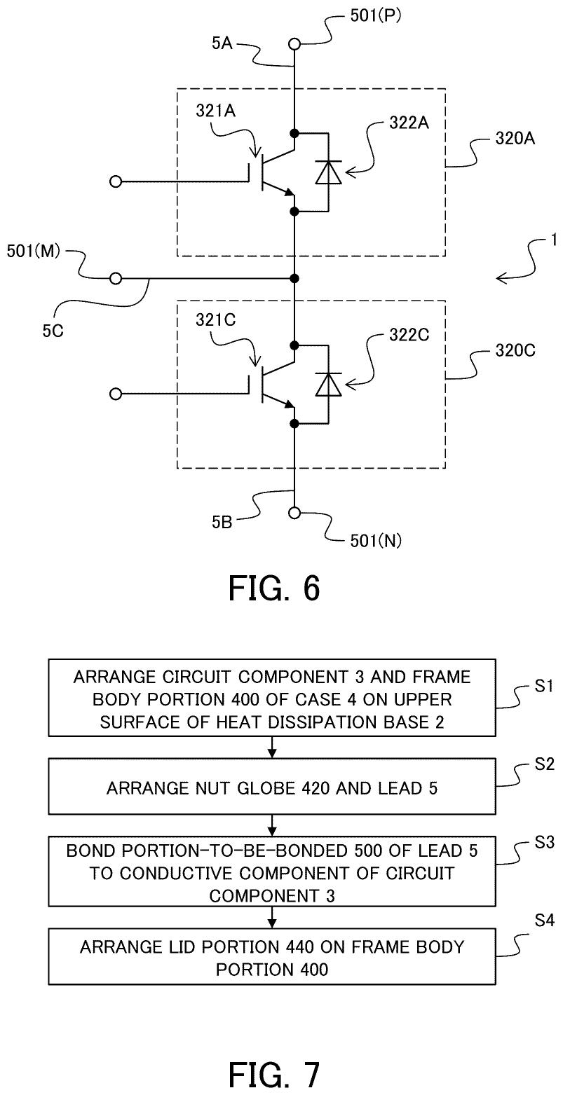

FIG. 1 is a plan view of a semiconductor module according to an embodiment. FIG. 2 is a cross-sectional view taken along line A-A′ in FIG. 1. FIG. 3 is a perspective view illustrating an example of a shape of a lead. FIG. 4 is a partially enlarged plan view in which the inside of a region B in FIG. 1 is enlarged. FIG. 5 is a cross-sectional view taken along line C-C′ in FIG. 4. FIG. 6 is an equivalent circuit diagram of an inverter circuit formed in the semiconductor module of FIG. 1. It is noted that FIGS. 1 and 4 illustrate a semiconductor module in a state in which a lid portion of a case 4 is not attached.

A semiconductor module 1 illustrated in FIGS. 1 to 5 includes a heat dissipation base 2, a circuit component 3, a case 4, and a lead 5. In the present specification, in a case where a plurality of identical components referred to by the same number are distinguished from each other, a reference sign represented by a combination of a number and an alphabet following the number is described, and in a case where a plurality of identical components are not distinguished from each other, a reference sign represented by only the number is described. For example, when referring to a specific circuit component among four circuit components 3A to 3D, a reference sign (any one of 3A to 3D) assigned to the specific circuit component is described in the drawing, and otherwise, it is simply described as the “circuit component 3”.

The circuit component 3 is disposed on the upper surface of the heat dissipation base 2, and may include a wiring board 300 and a semiconductor element (semiconductor chip) 320. The heat dissipation base 2 is a plate-shaped member that dissipates heat generated in the circuit component 3, and may be, for example, a metal plate such as copper or aluminum. The heat dissipation base 2 may be provided with a plurality of fins on the lower surface thereof. The heat dissipation base 2 may be a part of a cooler 6 or a component connected to the cooler 6. That is, the cooler 6 is an optional component in the semiconductor module 1 of the present embodiment.

The wiring board 300 includes an insulating substrate 301, a plurality of conductor patterns including a conductor pattern 302 disposed on the upper surface of the insulating substrate 301, and a heat dissipation pattern 303 disposed on the lower surface of the insulating substrate 301. The wiring board 300 may be a direct copper bonding (DCB) substrate or an active metal brazing (AMB) substrate, but the present invention is not limited thereto. The insulating substrate 301 may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 301 may be a substrate obtained by molding an insulating resin such as epoxy resin into a sheet shape, a substrate obtained by impregnating a base material such as a glass fiber with an insulating resin, a substrate obtained by coating the surface of a flat plate-shaped metal core with an insulating resin, or the like.

The plurality of conductor patterns including the conductor pattern 302 disposed on the upper surface of the insulating substrate 301 is used as a wiring member in an electronic circuit such as an inverter circuit formed in the semiconductor module 1. A portion-to-be-bonded 500 of the lead 5 and an electrode (not illustrated) on the lower surface of the semiconductor element 320 are bonded to the conductor pattern 302. The portion-to-be-bonded 500 of the lead 5 is bonded to the conductor pattern 302 by, for example, ultrasonic bonding. The electrode on the lower surface of the semiconductor element 320 is bonded to the conductor pattern 302 with, for example, a bonding material such as solder. The heat dissipation pattern 303 disposed on the lower surface of the insulating substrate 301 is used as a thermally conductive member that conducts heat generated by the semiconductor element 320 during operation of the semiconductor module 1 to the heat dissipation base 2. The plurality of conductor patterns including the conductor pattern 302 and the heat dissipation pattern 303 are formed of, for example, a metal foil such as copper or aluminum. The heat dissipation pattern 303 of the wiring board 300 is thermally connected to the upper surface of the heat dissipation base 2 by a bonding material such as solder or a thermally conductive member such as thermal grease or thermal compound.

The case 4 for accommodating the circuit component 3 is also disposed on the upper surface of the heat dissipation base 2. The case 4 includes a frame body portion 400 having open ends on the upper surface and the lower surface of the frame body portion, and a nut globe 420 (420A to 420C) and a lid portion 440 disposed on the upper surface of the frame body portion 400. The nut globe 420 is an insulating component provided with a nut accommodating portion 422 having a recessed shape for accommodating a nut 7 on an upper surface 421 serving as a front surface of the case 4. The frame body portion 400, the nut globe 420, and the lid portion 440 are, for example, made of an insulating resin having high electrical insulation properties, heat resistance, and dimensional stability, such as an epoxy resin or a polyphenylene sulfide (PPS) resin. The nut globe 420 and the lid portion 440 are disposed on the upper surface of the frame body portion 400 so as to form a gap for extending an external terminal portion 501 of the lead 5 where the portion-to-be-bonded 500 is bonded to the conductor pattern 302 to the outside of the case 4. The frame body portion 400 of the case 4 according to the present embodiment is provided with a beam portion 401 and a protrusion portion 402 on the inner peripheral wall surface. The beam portion 401 is in contact with the upper surface of an arm portion 508 of a third lead 5C, and the protrusion portion 402 is in contact with the upper surface of a protrusion portion 509 of the third lead 5C.

The external terminal portion 501 of the lead 5 can be a main terminal in the semiconductor module 1 in which the inverter circuit is formed. In the semiconductor module 1, for example, a half-bridge inverter circuit as illustrated in FIG. 6 is formed. The half-bridge inverter circuit includes two switching elements 321 connected in series and diode elements 322 respectively connected in anti-parallel to the switching elements 321. The switching element 321 may be, for example, an insulated gate bipolar transistor (IGBT), a power metal oxide semiconductor field effect transistor (MOSFET) element, a bipolar junction transistor (BJT) element, or the like. The diode element 322 may be, for example, a free wheeling diode (FWD) element, a Schottky barrier diode (SBD), a junction barrier Schottky (JBS) diode, a merged PN Schottky (MPS) diode, a PN diode, or the like. When the switching element 321 is the IGBT element, the collector of one switching element 321A of the two switching elements 321A and 321C connected in series is connected to a first lead 5A, and the emitter of the other switching element 321C is connected to a second lead 5B. The emitter of the switching element 321A and the collector of the switching element 321C are connected to a third lead 5C. The gate of the switching element 321 is connected to a control terminal (not illustrated). The emitter of the switching element 321 may be connected to a control terminal (for example, a terminal connected to a circuit that generates a control signal to be applied to a gate that may be referred to as an auxiliary emitter terminal, an emitter sense terminal, or the like) different from the lead 5. When the switching element 321 is the power MOSFET, the drain of one switching element 321A is connected to the first lead 5A, and the source of the other switching element 321C is connected to the second lead 5B. The source of the switching element 321A and the drain of the switching element 321C are connected to the third lead 5C. A source in a case where the switching element 321 is the power MOSFET may also be connected to a control terminal (for example, a terminal connected to a circuit that generates a control signal to be applied to a gate that may be referred to as an auxiliary source terminal or the like) different from the lead 5. The switching element 321 and the diode element 322 described above may be separate semiconductor elements 320, or may be one semiconductor element 320 in which both elements are formed. The switching element 321 illustrated as one element in FIG. 6 may be a plurality of switching elements formed in a plurality of semiconductor elements 320 and connected in parallel, and the diode elements 322 may be respectively connected in anti-parallel to the plurality of switching elements. The switching element 321 is not limited to silicon (Si), and may be formed of a wide bandgap semiconductor material such as silicon carbide (SiC) or gallium nitride (GaN).

The external terminal portion 501 of the lead 5 extends in a direction along the upper surface of the wiring board 300, and a through hole 510 having an opening end in the plate thickness direction is formed. The external terminal portion 501 of the first lead 5A is disposed in parallel with the upper surface 421 of the first nut globe 420A such that the through hole 510 overlaps a threaded hole of the nut 7 accommodated in the nut accommodating portion in plan view of the upper surface 421 of the first nut globe 420A. The external terminal portion 501 of the second lead 5B is disposed in parallel with the upper surface 421 of the second nut globe 420B such that the through hole 510 overlaps a threaded hole of the nut 7 accommodated in the nut accommodating portion in plan view of the upper surface 421 of the second nut globe 420B. The first lead 5A and the second lead 5B are integrally supported by an insulating support member 8, and the insulating support member 8 is fitted between the first nut globe 420A and the second nut globe 420B, whereby a positional relationship between the external terminal portion 501 of each lead 5 and the upper surface 421 of the nut globe 420 is maintained.

The external terminal portion 501 of the third lead 5C is disposed in parallel with the upper surface 421 of the third nut globe 420C such that the through hole 510 overlaps a threaded hole of the nut 7 accommodated in the nut accommodating portion 422 in plan view of the upper surface 421 of the third nut globe 420C. The third lead 5C is bent at a boundary between the external terminal portion 501 and a first intermediate portion 502 such that the first intermediate portion 502 connected to the external terminal portion 501 is disposed parallel to a side surface 423 connected to the upper surface 421 of the third nut globe 420C. The first intermediate portion 502 of the third lead 5C passes through between the third nut globe 420C and the lid portion 440.

The lead 5 includes, between the portion-to-be-bonded 500 and the first intermediate portion 502, a second intermediate portion 503 connected to the first intermediate portion 502 and a rising portion 504 connecting the second intermediate portion 503 to the portion-to-be-bonded 500. In the third lead 5C, the arm portion 508 is provided in the second intermediate portion 503. The arm portion 508 extends from the second intermediate portion 503 in a direction opposite to the extending direction of the portion-to-be-bonded 500 in XY plan view, and is provided such that the external terminal portion 501 is disposed in parallel with the upper surface 421 of the third nut globe 420C when the upper surface of the arm portion 508 abuts on the lower surface of the beam portion 401 of the case 4. Furthermore, the first intermediate portion 502 of the third lead 5C is provided with the protrusion portion 509 protruding toward the inner peripheral wall surface of the frame body portion 400 located at the end in the direction parallel to the side surface 423 of the third nut globe 420C. The protrusion portion 509 of the third lead 5C is provided such that the external terminal portion 501 is disposed in parallel with the upper surface 421 of the third nut globe 420C when the upper surface abuts on the lower surface of the protrusion portion 402 of the frame body portion 400 of the case 4.

FIG. 7 is a flowchart illustrating a manufacturing step of the semiconductor module according to the first embodiment. The manufacturing step of the semiconductor module 1 of the present embodiment includes, for example, a first step (S1) of arranging the circuit component 3 and the frame body portion 400 of the case 4 on the upper surface of the heat dissipation base 2 illustrated in FIG. 7, a second step (S2) of arranging the nut globe 420 accommodating the nut 7 in the nut accommodating portion 422 and the lead 5, a third step (S3) of bonding the portion-to-be-bonded 500 of the lead 5 to the conductive component (the conductor pattern 302 of the wiring board 300) of the circuit component 3, and a fourth step (S4) of arranging the lid portion 440 on the upper surface of the frame body portion 400. In the first step, for example, the wiring board 300 is disposed on the upper surface of the heat dissipation base 2 with a bonding material such as solder interposed therebetween, and the semiconductor element 320 is further disposed on the upper surface of the wiring board 300 with a bonding material such as solder interposed therebetween, and then the bonding material is heated and melted. Thereafter, the frame body portion 400 of the case is bonded to the upper surface of the heat dissipation base 2 with an adhesive. In the second step, for example, the lead 5 is disposed such that the portion-to-be-bonded 500 is positioned at a predetermined position on the upper surface of the circuit component 3, and the nut globe 420 is attached to the upper surface of the frame body portion 400 with an adhesive or by press fitting. In the third step, for example, the portion-to-be-bonded 500 of the lead 5 is bonded to the conductor pattern 302 of the wiring board 300 by ultrasonic bonding. In the fourth step, for example, the lid portion 440 is attached to the upper surface of the frame body portion 400 by press fitting so as to close the opening at the upper end of the frame body portion 400 secured for ultrasonic bonding in the third step.

However, when ultrasonic bonding is performed in the third step, the external terminal portion 501 of the lead 5 may rise from the upper surface 421 of the nut globe 420, and the parallelism may decrease (deteriorate). For example, in the third lead 5C, since the external terminal portion 501 and the first intermediate portion 502 far from the portion-to-be-bonded 500 are separated from the third nut globe 420C, and the first intermediate portion 502 is also separated from the lid portion 440, the parallelism is likely to decrease due to ultrasonic bonding.

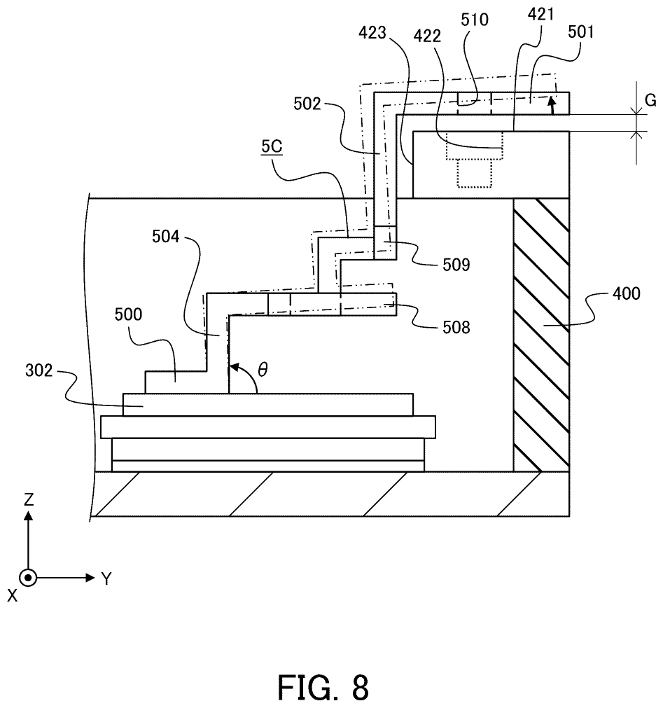

FIG. 8 is a diagram illustrating floating of the external terminal portion of the lead. The third lead 5C is formed so as to be disposed parallel to the upper surface 421 in a state in which the external terminal portion 501 is separated from the upper surface 421 of the third nut globe 420C by a predetermined distance G when the lower surface (bonding surface) of the portion-to-be-bonded 500 is brought into contact with the conductor pattern 302 of the wiring board 300. However, when the portion-to-be-bonded 500 is bonded to the conductor pattern 302 by ultrasonic bonding, the third lead 5C is deformed in a direction in which a rising angle θ of the rising portion 504 increases. The rising angle θ can be a bending angle of the rising portion 504 in which the angle θ when the rising portion 504 is parallel to the portion-to-be-bonded 500 is defined as 0°.

In a case where the beam portion 401 and the protrusion portion 402 described above are not provided in the frame body portion 400 of the case 4, when the rising angle θ of the rising portion 504 increases due to ultrasonic bonding, as illustrated in FIG. 8, the third lead 5C is rotated in a direction in which the distance G between the external terminal portion 501 and the upper surface 421 of the third nut globe 420C increases with the boundary between the portion-to-be-bonded 500 and the rising portion 504 as a fulcrum. In addition, as illustrated in FIGS. 2 and 11, a gap between the side surface 423 of the third nut globe 420C through which the first intermediate portion 502 of the third lead 5C passes and a side surface 441 of the lid portion 440 is larger than a dimension corresponding to the plate thickness of the first intermediate portion 502 due to the clearance for improvement in assembly workability of the semiconductor module 1. Therefore, when the rising angle θ of the rising portion 504 increases due to ultrasonic bonding, the parallelism in which the external terminal portion 501 is inclined relative to the upper surface 421 of the third nut globe 420C becomes low. Therefore, for example, when a shaft of a bolt is inserted into the through hole 510 of the external terminal portion 501 and screwed into the nut 7 (refer to FIG. 2) in order to connect a component such as a cable terminal to the external terminal portion 501 of the third lead 5C, there arises a problem that workability deteriorates.

In the semiconductor device of WO 2017/122473 A, in plan view of a main surface portion of a main terminal, an extending direction of the main surface portion from a side surface portion is different from an extending direction of a tip portion from a fixing portion. Therefore, when the tip portion of the main terminal is bonded to an electronic circuit of a substrate by ultrasonic bonding, the main surface portion is inclined in a direction in which the angle of the extending direction of a boundary line between the main surface portion and the side surface portion with respect to an in-plane direction of the front surface of a main surface facing portion of an insertion portion increases. In addition, a universal guide for fixing a main electrode to a case in a semiconductor device of JP 2009-21286 A fixes movement of the position of the main electrode in the left-and-right direction, movement in the forward-and-rearward direction, and movement in the vertical direction. In the semiconductor device of JP 2009-21286 A, one end of a main electrode 24 is bonded to the wiring on an insulating substrate 20 by a bonding material such as solder. However, in a case where the main electrode is bonded by ultrasonic bonding as described above, movement different from movement in the left-and-right direction, movement in the forward-and-rearward direction, and movement in the vertical direction occurs in the main electrode, and a phenomenon similar to the floating of the external terminal portion described above with reference to FIG. 8 may occur.

On the other hand, as described above, the frame body portion 400 of the case 4 according to the present embodiment is provided with the beam portion 401 that abuts on the upper surface of the arm portion 508 provided on the second intermediate portion 503 of the third lead 5C and the protrusion portion 402 that abuts on the upper surface of the protrusion portion 509 provided on the first intermediate portion 502. Therefore, when the third lead 5C is ultrasonically bonded in the third step (S3) illustrated in FIG. 7, the beam portion 401 and the protrusion portion 402 provided on the frame body portion 400 of the case 4 prevent the arm portion 508 of the third lead 5C and the first intermediate portion 502 from being displaced in an upward direction (a direction away from the upper surface of the conductor pattern 302 of the wiring board 300 to which the portion-to-be-bonded 500 is bonded). Therefore, in the third lead 5C, deformation in which the rising angle θ of the rising portion 504 increases does not occur, and the parallelism between the external terminal portion 501 of the third lead 5C and the upper surface 421 of the third nut globe 420C can be prevented from decreasing.

It is noted that a configuration for suppressing deformation in which the rising angle θ of the rising portion 504 of the third lead 5C increases is not limited to the above-described combination. In the frame body portion 400 of the case 4, only one of the beam portion 401 and the protrusion portion 402 (for example, only the beam portion 401) may be provided. In addition, the beam portion 401 and the protrusion portion 402 described above are merely examples of an abutting portion that abuts on the third lead 5C so as to prevent an increase in the angle of the third lead 5C in the extending direction of the external terminal portion 501 with respect to the wiring board 300 due to rotation of the intermediate portions 502 and 503 of the third lead 5C and the external terminal portion 501 with the boundary between the portion-to-be-bonded 500 and the rising portion 504 as a fulcrum. That is, instead of the beam portion 401, a pair of protrusion portions protruding from the inner peripheral wall surface of the case 4 may be provided. Instead of the beam portion 401, for example, a through hole or a recessed portion into which the arm portion 508 of the third lead 5C is inserted may be provided in the inner peripheral wall surface of the case 4 or a wall portion protruding from the inner peripheral wall surface. The third lead 5C is not limited to the shape illustrated in FIG. 3 and the like. The arm portion 508 and the protrusion portion 509 of the third lead 5C may have any shape as long as they abut on an abutting portion such as the beam portion 401 of the frame body portion 400 of the case 4 so as to prevent an increase in the angle of the external terminal portion 501 in the extending direction with respect to the wiring board 300 due to rotation of the intermediate portions 502 and 503 of the third lead 5C and the external terminal portion 501. The arm portion 508 and the protrusion portion 509 may be omitted, and a surface of the second intermediate portion 503 facing upwards (a direction opposite to the wiring board 300) may abut on the abutting portion such as the beam portion 401 of the case 4. In the third lead 5C, the number of the portions-to-be-bonded 500 may be other than four, or the number of the external terminal portions 501 may be other than three.

In the semiconductor module 1 according to the present embodiment, for example, the first lead 5A and the second lead 5B may also be configured such that rotation of the external terminal portion 501 due to ultrasonic bonding is prevented by the abutting portion of the case 4. Further, in the semiconductor module 1 according to the present embodiment, the nut globe 420 may be formed to be integrated with the frame body portion 400.

### Second Embodiment

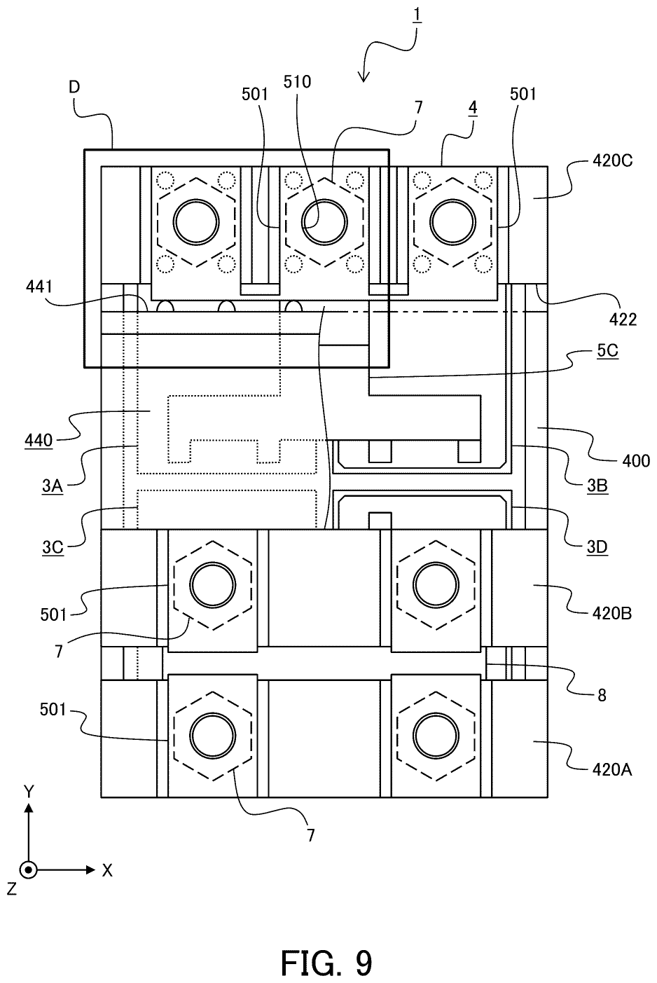

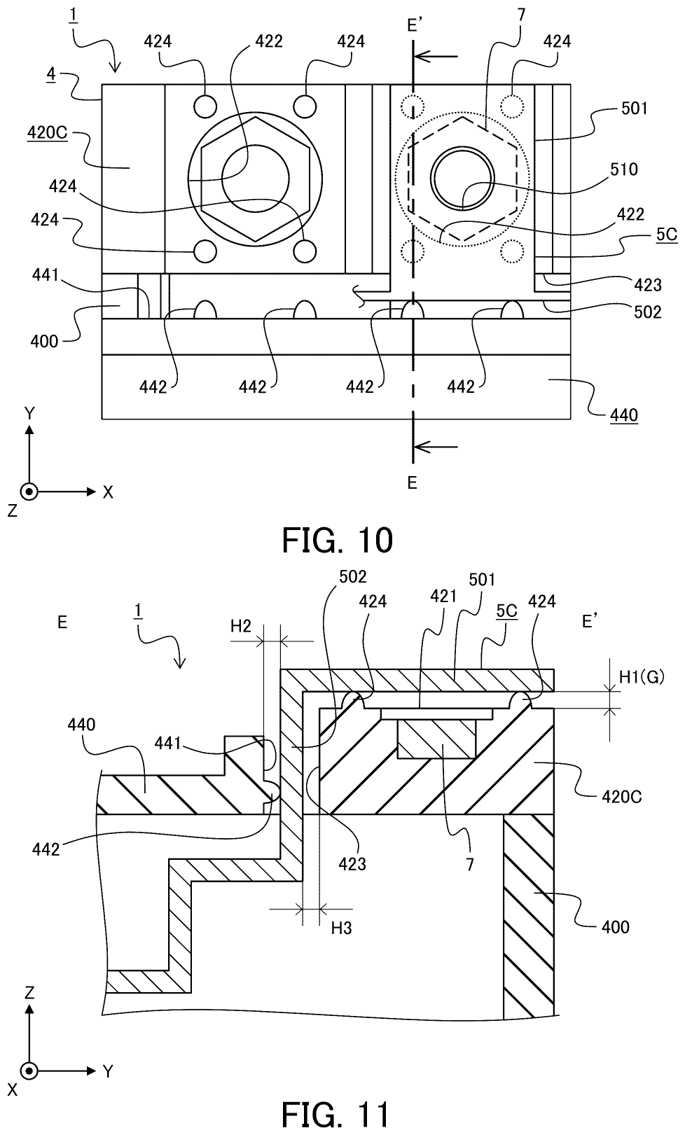

FIG. 9 is a plan view of a semiconductor module according to a second embodiment. FIG. 10 is a partially enlarged plan view in which the inside of a region D in FIG. 9 is enlarged. FIG. 11 is a cross-sectional view taken along line E-E′ of FIG. 10. FIG. 9 illustrates a semiconductor module 1 in which a part of the lid portion 440 is omitted, and FIG. 10 illustrates a semiconductor module 1 in which a part of the third lead 5C is omitted.

The semiconductor module 1 illustrated in FIGS. 9 to 11 can be similar to the semiconductor module 1 described in the first embodiment except for the following first difference and second difference. The first difference is that the arm portion 508 and the protrusion portion 509 of the third lead 5C and the beam portion 401 and the protrusion portion 402 of the frame body portion 400 of the case 4 are not provided. The second difference is that a protrusion portion 424 and a protrusion portion 442 are respectively provided on the upper surface 421 of the third nut globe 420C and the side surface 441 of the lid portion 440 facing the first intermediate portion 502 of the third lead 5C.

The plurality of (four in FIGS. 9 and 10) protrusion portions 424 of the third nut globe 420C are provided in a region of the upper surface 421 overlapping the external terminal portion 501 of the third lead 5C in plan view. A height H1 of the protrusion portion 424 of the third nut globe 420C and a height H2 of the protrusion portion 442 of the lid portion 440 are set such that the external terminal portion 501 of the third lead 5C extends parallel to the upper surface 421 at a position separated from the upper surface 421 of the third nut globe 420C by a distance G (refer to FIG. 8) corresponding to the height H1. The height H1 of the protrusion portion 424 and the height H2 of the protrusion portion 442 of the lid portion 440 are not limited to specific heights. The height H2 of the protrusion portion 442 can be set based on, for example, a clearance between the side surface 441 of the lid portion 440 and the first intermediate portion 502 of the third lead 5C and a clearance H3 between the side surface 423 of the third nut globe 420C and the first intermediate portion 502 of the third lead 5C. The protrusion portions 424 and 442 are not limited to a specific shape, but by having a spherical shape or the like in which a contact area with the third lead 5C is reduced, for example, it is possible to prevent deterioration in workability when the lid portion 440 is press-fitted between the second nut globe 420B (refer to FIG. 9) and the first intermediate portion 502 of the third lead 5C and is disposed on the upper surface of the frame body portion 400.

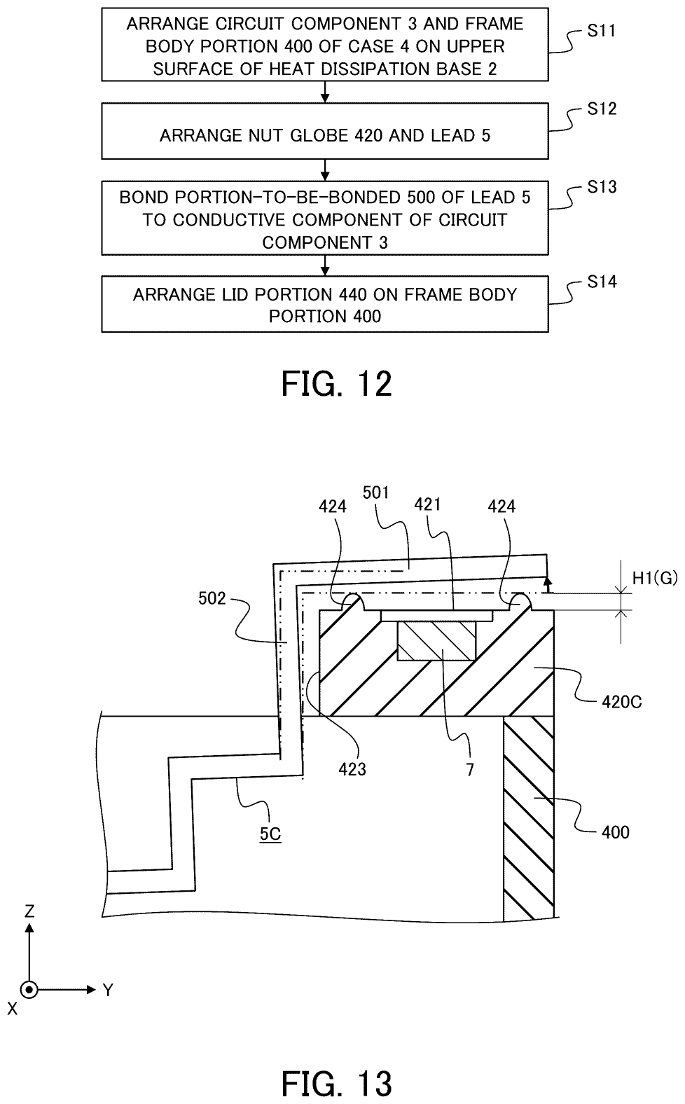

FIG. 12 is a flowchart illustrating a manufacturing step of the semiconductor module according to the second embodiment. FIG. 13 is a diagram illustrating the effects of a configuration of the semiconductor module according to the second embodiment. The manufacturing step of the semiconductor module 1 of the present embodiment includes, for example, a first step (S11) of arranging the circuit component 3 and the frame body portion 400 of the case 4 on the upper surface of the heat dissipation base 2 illustrated in FIG. 12, a second step (S12) of arranging the nut globe 420 accommodating the nut 7 in the nut accommodating portion 422 and the lead 5, a third step (S13) of bonding the portion-to-be-bonded 500 of the lead 5 to the conductive component (the conductor pattern 302 of the wiring board 300) of the circuit component 3, and a fourth step (S14) of arranging the lid portion 440 on the upper surface of the frame body portion 400. The first step (S11), the second step (S12), the third step (S13), and the fourth step (S14) illustrated in FIG. 12 correspond to the first step (S1), the second step (S2), the third step (S3), and the fourth step (S4) described above with reference to FIG. 7 in the first embodiment, respectively.

The frame body portion 400 used in the semiconductor module 1 of the present embodiment is not provided with a portion for preventing the intermediate portions 502 and 503 of the third lead 5C and the external terminal portion 501 from rotating at the time of ultrasonic bonding, such as the beam portion 401. Therefore, when the portion-to-be-bonded 500 of the third lead 5C is bonded to the conductor pattern 302 of the wiring board 300 by ultrasonic bonding in the third step, as illustrated by a solid line in FIG. 13, the external terminal portion 501 of the third lead 5C is separated from the protrusion portion 424 disposed on the upper surface 421 of the third nut globe 420C and floats. At this time, the first intermediate portion 502 of the third lead 5C is displaced in a direction in which a distance from the side surface 423 of the third nut globe 420C increases. However, when the lid portion 440 is disposed on the upper surface of the frame body portion 400 in the subsequent fourth step, the protrusion portion 442 provided on the side surface 441 of the lid portion 440 abuts on the first intermediate portion 502 of the third lead 5C, and the first intermediate portion 502 is displaced in a direction approaching the side surface 423 of the third nut globe 420C (a position indicated by a two-dot chain line in FIG. 13). At this time, since the third lead 5C rotates in a direction in which the rising angle θ decreases with the boundary between the portion-to-be-bonded 500 and the rising portion 504 as a fulcrum, the external terminal portion 501 is displaced in a direction approaching the upper surface 421 of the third nut globe 420C. Therefore, after the lid portion 440 is disposed on the upper surface of the frame body portion 400, as illustrated in FIG. 11, the external terminal portion 501 abuts on the protrusion portion 424 disposed on the upper surface 421 of the third nut globe 420C and is supported in a state of being parallel to the upper surface 421.

As described above, in the semiconductor module 1 of the present embodiment, the third lead 5C deformed by ultrasonic bonding is corrected in a direction returning to the shape before bonding (before deformation) by the protrusion portion 442 of the lid portion 440. That is, in the semiconductor module 1 of the present embodiment, an increase in the angle of the external terminal portion 501 in the extending direction with respect to the wiring board 300 due to rotation of the external terminal portion 501 of the third lead 5C is prevented by the protrusion portion 442 provided on the side surface 441 of the lid portion 440. As a result, in the semiconductor module 1 of the present embodiment as well, it is possible to prevent deterioration in parallelism between the external terminal portion 501 of the third lead 5C and the upper surface 421 of the third nut globe 420C. In addition, for example, even in a case where a distance from the side surface 441 of the lid portion 440 to the side surface 423 of the third nut globe 420C is shortened due to tolerance or the like, and the rising angle θ (refer to FIG. 8) of the rising portion 504 becomes smaller than the angle before bonding when the lid portion 440 is disposed on the upper surface of the frame body portion 400, a distance between the external terminal portion 501 of the third lead 5C and the upper surface 421 of the third nut globe 420C is maintained at the height H1 of the protrusion portion 424 by the protrusion portion 424 disposed on the upper surface 421 of the third nut globe 420C, thereby making it possible to suppress deterioration in parallelism. In addition, since it is possible to prevent deterioration in parallelism between the external terminal portion 501 of the third lead 5C and the upper surface 421 of the third nut globe 420C without providing a protrusion portion on the side surface 423 of the third nut globe 420C, for example, it is also possible to prevent the third nut globe 420C from being detached from the upper surface of the frame body portion 400 due to application of a pressing load to the side surface 423 of the third nut globe 420C.

The protrusion portion 424 of the third nut globe 420C can be formed to be integrated with the third nut globe 420C by, for example, providing a recessed portion corresponding to the protrusion portion 424 in a mold used when the third nut globe 420C is formed by transfer molding. The protrusion portion 442 of the lid portion 440 can also be formed to be integrated with the lid portion 440 by providing a recessed portion corresponding to the protrusion portion 442 in a mold used when the lid portion 440 is formed by transfer molding. The number and arrangement of the protrusion portions 424 and 442 are not limited to a specific number and arrangement. For example, as illustrated in FIG. 11 and the like, in a case where a wall portion protruding upwards is provided at an end portion on the side surface 441 side of the upper surface of the lid portion 440, the protrusion portion 442 is disposed in a region where a thickness from the side surface 441 below the lower end of the wall portion is larger in the side surface 441 of the lid portion 440, thereby making it possible to suppress the deformation of the lid portion 440 (wall portion) due to reaction force from the third lead 5C to be corrected.

It is noted that, in the semiconductor module 1 according to the present embodiment, for example, the first lead 5A and the second lead 5B may also correct the external terminal portion 501 rotated by ultrasonic bonding by the protrusion portion of the upper surface 421 of the corresponding nut globe 420 and the protrusion portion of the lid portion 440. Further, in the semiconductor module 1 according to the present embodiment, the nut globe 420 may be formed to be integrated with the frame body portion 400.

The semiconductor module 1 of the above-described embodiment is not limited to that for a specific application, but in particular, the semiconductor module 1 including the cooler 6 is suitable for use in a high-temperature environment. For example, the semiconductor module 1 of the above-described embodiment may be applied to a power conversion apparatus such as an inverter apparatus of an in-vehicle motor. The vehicle to which the semiconductor module 1 is applied is not limited to a four-wheeled vehicle, and may be a two-wheeled vehicle, a railway vehicle, or the like. The semiconductor module 1 may be applied to, for example, an industrial power conversion apparatus such as an inverter apparatus that drives a motor of an elevator, an escalator, or an air conditioning system of a building. The circuit formed in the semiconductor module 1 is not limited to the half-bridge inverter circuit illustrated in FIG. 6. The circuit formed in the semiconductor module 1 is not limited to the inverter circuit, and may be another circuit or may include an inverter circuit and another circuit.

Hereinafter, feature points in the above-described embodiments will be summarized.

The semiconductor module according to the above-described embodiment include: a circuit component including a wiring board and a semiconductor element mounted on the wiring board; a lead bonded to a conductor pattern of the circuit component; and a case having a recessed portion formed in a front surface thereof, the recessed portion accommodating a nut therein, in which the case includes a frame body portion surrounding the wiring board and a lid portion closing an opening of the frame body portion, the lead includes an external terminal portion extending along the wiring board, a portion-to-be-bonded bonded to the conductor pattern, and an intermediate portion connecting the portion-to-be-bonded to the external terminal portion, and the case is provided with an abutting portion abutting on the lead so as to prevent an increase in an angle of the external terminal portion of the lead in an extending direction relative to the wiring board, in which the increase in an angle is caused by rotation of the intermediate portion and the external terminal portion of the lead having a boundary between the portion-to-be-bonded and the intermediate portion as a fulcrum.

In the semiconductor module according to the above-described embodiment, the case further includes a nut globe disposed at an open end of the frame body portion, the nut globe having the recessed portion configured to allow the nut to be accommodated therein, the abutting portion of the case prevents an increase in an angle of the external terminal portion of the lead in the extending direction relative to the front surface of the nut globe, the increase in an angle being caused by the rotation of the external terminal portion, and the abutting portion of the case is provided on the frame body portion, abuts on a back surface of a surface of the intermediate portion of the lead, the surface facing the wiring board, and prevents the intermediate portion of the lead from rotating in a direction away from the wiring board.

In the semiconductor module according to the above-described embodiment, the lid portion is disposed to be spaced apart from the nut globe by a predetermined distance, the abutting portion of the case is a protrusion portion protruding from an inner peripheral wall surface of the frame body portion, and an arm portion is provided at the intermediate portion of the lead, the arm portion having a height from the wiring board, the height being lower than a height of the protrusion portion, and abutting on the protrusion portion.

In the semiconductor module according to the above-described embodiment, the case further includes a nut globe disposed at an open end of the frame body portion, the nut globe having the recessed portion configured to allow the nut to be accommodated therein, the abutting portion of the case prevents an increase in an angle of the external terminal portion of the lead in the extending direction relative to the front surface of the nut globe, the increase in an angle being caused by the rotation of the external terminal portion, the lid portion is disposed to be spaced apart from the nut globe by a predetermined distance, the abutting portion of the case includes a first protrusion portion and a second protrusion portion, the first protrusion portion being disposed on the front surface of the nut globe, the second protrusion portion being disposed on a side surface of the lid portion, the side surface facing the intermediate portion of the lead, and the external terminal portion of the lead abuts on the first protrusion portion, and the intermediate portion of the lead abuts on the second protrusion portion.

In the semiconductor module according to the above-described embodiment, each of the first protrusion portion and the second protrusion portion has a spherical tip portion abutting on the lead.

The semiconductor module according to the above-described embodiment has an inverter circuit formed therein, the inverter circuit including the circuit component.

The semiconductor module according to the above-described embodiment further includes a heat dissipation base configured to allow the circuit component and the case to be disposed on a first surface thereof.

It is noted that the present invention is not limited to the above-described embodiments, and various changes, substitutions, and modifications may be made without departing from the spirit of the technical idea. Furthermore, when the technical concept can be realized in another manner by the progress of the technology or another derived technology, the present invention may be implemented using the method. Therefore, the claims cover all implementations that may be included within the scope of the technical idea.

### INDUSTRIAL APPLICABILITY

As described above, the present invention has an effect of making it possible to prevent deterioration in parallelism between an external terminal portion of a lead of a semiconductor module and a surface (front surface) of a case and making it possible to easily perform an operation of attaching a component such as a cable terminal to the external terminal portion of the lead, and is particularly useful for a semiconductor module for industrial or vehicle used as a power conversion device.

What is claimed is:

1. A semiconductor module, comprising:
a circuit component including a wiring board having a conductor pattern and a semiconductor element mounted on the conductor pattern;
a lead bonded to the conductor pattern; and
a case including a frame body surrounding a case opening in which the wiring board is disposed, and a lid closing the case opening, the case having at a case front surface thereof a recess in which a nut is to be accommodated, wherein
the lead includes an external terminal extending in an extending direction along the case front surface, a bonded member bonded to the conductor pattern, and an intermediate member connecting the bonded member to the external terminal, and
the case has an abutting member that contacts the lead to prevent the lead from rotating about a boundary between the bonded member and the intermediate member as a fulcrum, thereby preventing an angle between the extending direction of the external terminal and the case front surface from increasing.

2. The semiconductor module according to claim 1, wherein
the case further includes a nut globe disposed at the frame body and located at an end of the case opening, a nut globe front surface of the nut globe forming the case front surface so that the recess is formed in the nut globe front surface,
the abutting member prevents an increase in an angle between the extending direction of the external terminal and the nut globe front surface, by preventing the lead from rotating, and
the abutting member is provided on the frame body, contacts an upper surface of the intermediate member that is opposite to a lower surface of the intermediate member facing the wiring board, and prevents the lead from rotating in a direction that moves the external terminal portion away from the nut globe front surface.

3. The semiconductor module according to claim 2, wherein
the lid is spaced apart from the nut globe by a predetermined distance,
the abutting member is a protrusion protruding from an inner peripheral wall surface of the frame body toward an inside of the case opening, and
the lead further includes an arm at the intermediate member, the arm being located at a position from the wiring board in a direction orthogonal to the wiring board that is lower than a position of the protrusion so as to contact the protrusion.

4. The semiconductor module according to claim 1, wherein
the case further includes a nut globe disposed at the frame body and located at an end of the case opening, a nut globe front surface of the nut globe forming the case front surface so that the recess is formed in the nut globe front surface of the nut globe,
the abutting member prevents an increase in an angle between the extending direction of the external terminal and the nut globe front surface, by preventing the lead from rotating,
the lid portion is spaced apart from the nut globe by a predetermined distance,
the abutting portion of the case includes a first protrusion and a second protrusion, the first protrusion being disposed on the nut globe front surface, the second protrusion being disposed on a side surface of the lid, the side surface facing the intermediate member, and
the external terminal contacts the first protrusion, and the intermediate member contacts on the second protrusion.

5. The semiconductor module according to claim 4, wherein each of the first protrusion and the second protrusion has a spherical shape at a tip thereof contacting the lead.

6. The semiconductor module according to claim 1, wherein the semiconductor module has an inverter circuit formed by the circuit component.

7. The semiconductor module according to claim 1, further comprising a heat dissipation base having the circuit component and the case disposed on a base front surface thereof.
